(19) United States
(12) Patent Application Publication
(10) Pub. No.: US 2009/0151991 A1
(43) Pub. Date: Jun. 18, 2009

(54) MOUNTING STRUCTURE, ELECTROOPTIC DEVICE, AND ELECTRONIC APPARATUS

(75) Inventors: Naosuke FURUTANI, Shiojiri-shi (JP); Shinichi KOBAYASHI, Azumino-shi (JP); Yutaka FUJIMAKI, Shiojiri-shi (JP)

Correspondence Address: LOWE HAUPTMAN HAM & BERNER, LLP, 1700 DIAGONAL ROAD, SUITE 300, ALEXANDRIA, VA, 22314, US

(73) Assignee: EPSON IMAGING DEVICES CORPORATION, Nagano (JP)

(21) Appl. No.: 12/257,930

(22) Filed: Oct. 24, 2008

(30) Foreign Application Priority Data
Dec. 14, 2007 (JP) 2007-322919
Jul. 15, 2008 (JP) 2008-183506

(51) Int. Cl. H05K 1/16

(52) U.S. Cl. 174/260

(57) ABSTRACT

A mounting structure includes: a wiring board; an electronic element which is mounted in the wiring board and supplied with a periodic signal; and a first opening which is formed in the wiring board along one side of the electronic element in a longitudinal direction of the electronic element. The opening is opposed to the entire one side of the electronic element.

### BACKGROUND

1. Technical Field

The present invention relates to a mounting structure, an electrooptic device, and an electronic apparatus, and particularly to the mounting structure in which an electronic element such as a laminated ceramic capacitor is mounted on a wiring board.

2. Related Art

In general, a mounting structure in which electronic elements are mounted on a wiring board such as a flexible printed circuit is disposed within various electronic apparatuses. Such a mounting structure includes mainly include a capacitor which is a constituent element of an electric circuit. In particular, as electric devices have recently become small and thin, a minute laminated ceramic capacitor of a surface mounting type is widely used in order to miniaturize the electronic elements and promote process automation.

JP-A-2006-309184 (FIGS. 2 and 13, etc.) and JP-A-2004-153121 disclose such a mounting structure in which the minute electronic elements are mounted on the wiring board. JP-A-2006-309184 describes a structure capable of preventing breakage of a terminal on a board side by providing openings (denoted by Reference Numerals 25 and 125), which has an L shape or a U shape in plan view and surrounds a mount area of a semiconductor element 23, in the vicinity of the corners of a circuit board 3 included in an electrooptic device. In addition, JP-A-2004-153121 describes a structure in which a surface mounting process is performed by allowing a capacitor body 17 to float from a wiring board by a metal member or the like in order to suppress an oscillation sound generated by the laminated ceramic capacitor.

However, in the electronic apparatus including the wiring board on which electronic elements are surface-mounted in the above-mentioned manner, a harsh sound to the ear is generated since oscillation generated from the electronic elements is propagated to the wiring board. Accordingly, this sound may degrade the quality of electronic apparatuses. In particular, there occurs a problem in that circumstance may deteriorate in portable electronic devices such as cellular phones at the time of carrying the cellular phones.

In the structure disclosed in JP-A-2006-309184 mentioned above, the openings provided in the wiring board are formed only outside the corners of the electronic elements or formed only outside the terminal wiring board side which is connected to terminals of the electronic elements. Therefore, such a configuration is effective for prevention of the breakage of the terminal on the wiring board side, but there occurs a problem in that the sound generated from the electronic elements cannot effectively be reduced.

In the structure disclosed in JP-A-2004-153121 mentioned above, no advantage of surface mounting such as the thinness of the mounting structure or the mounting process automation is achieved since the surface mounting type electronic elements cannot be directly on the wiring board. Therefore, an obstacle to the surface mounting may occur at the time of the miniaturization and thinness of recent electronic apparatuses or at the time of reduction in manufacturing cost.

### SUMMARY

An advantage of some aspects of the invention is that it provides a mounting structure, an electrooptic device, and an electronic apparatus capable of effectively reducing a sound generated due to oscillation of electronic elements which are surface-mounted on a wiring board.

According to an aspect of the invention, there is provided a mounting structure including: a wiring board; an electronic element which is mounted in the wiring board and supplied with a periodic signal; and a first opening which is formed in the wiring board along one side of the electronic element in a longitudinal direction of the electronic element. The opening is opposed to the entire one side of the electronic element. The electronic element may be formed so that voltage is applied in a direction intersecting a plane direction of the wiring board. As an example of the electronic element, there is used a ceramic capacitor having an inner structure formed by alternatively laminating a ceramic sheet as an electrostrictive material and an inner electrode. Examples of the electronic element generating such oscillation include another type capacitor or an inductor.

According to the thorough experiment made by the inventors, a sound decreases as a formation range of the opening surrounding the periphery of the electronic elements is larger and the opening is closer to the electronic elements. Actually, there is an area where the opening cannot be formed in the periphery of the electronic elements, since wirings conductively connected to electrodes of the electronic elements are present on a wiring board. Moreover, when the area where the opening cannot be formed becomes small, the breakage of the wiring board or the wiring easily occurs, thereby degrading a yield. Accordingly, since there is restriction on the formation range of the opening, it is necessary to provide the opening at a location and an in a mode in which oscillation propagation to the periphery of the wiring board can be reduced as effectively as possible.

It is considered that the sound is generated from the board surface or contact portions between the wiring board and other members while the oscillation generated from the electronic elements is propagated to the wiring board and propagated to the periphery of the wiring board. In this case, it was generally known that the oscillation generated from the electronic elements is propagated in an isotropic manner to the periphery. However, according to the experiment result of the inventors, it is proven that the sound generated due to the oscillation of the electronic elements can be more effectively reduced by providing the opening on the wiring board along an outer edge extending a longitudinal direction of the electronic elements, compared to the case where the opening is provided at another location or in another mode.

The generation of the sound is also caused by a location relation of the opening with respect to the wiring on the wiring board. With the miniaturization of the electronic elements, there is an increase in a configuration in which electrodes are provided in both ends in a longitudinal direction of the electronic elements. In this case, even when the electronic elements are miniaturized, it is advantageous to form wirings extending from the electrodes of both the ends on the outside in the longitudinal direction in the wiring board in order to ensure electrical reliability. In addition, with such a configuration of the electronic elements and the wirings, it is advantageous to form the opening along the outer edge extending in the longitudinal direction of the electronic elements in order to provide the opening in a possible large range of the periphery of the electronic elements. In this way, it can be configured so that the opening is formed in the large range of the periphery of the electronic elements even when the miniaturized electronic elements are mounted with a high density. Accordingly, it is considered that the oscillation generated from the electronic elements can be effectively reduced.

The other reason for generating the sound is that when a pair of the openings are provided on both sides of the electronic elements or the electronic elements are mounted so as to be adjacent to the end of the wiring board and the opening are provided on a side opposite the end of the wiring board, an area where the electronic elements are mounted between the pair of the openings or between the opening and the end of the wiring board has a narrow and long belt shape. Therefore, a flexible property is improved in the mount area and a width between the mount area and a contact portion other than the mount area becomes narrow. With such a configuration, it is difficult for the oscillation generated form the electronic elements to be propagated from the mount area to the periphery. In contrast, when the openings or the ends of the wiring board are provided on both sides in the longitudinal direction of the electronic elements, the width of the area where the electronic elements are mounted has a wide and short belt shape. Therefore, it is considered that the flexible property is low in the mount area and the oscillation generated from the electronic elements is easily propagated to the outside due to the wide width between the mount area and the contact portion other than the mount area.

According to the mounting structure having the above-described configuration, the first opening is adjacent to one side extending in the longitudinal direction in the outside edge of the electronic element and is provided at least across the length range of the electronic elements in the longitudinal direction. Since it is possible to effectively suppress the propagation of the oscillation to the area other than the area where the electronic elements are mounted, the sound can effectively be reduced. Here, by extending the first opening along the longitudinal direction, there is no occupation of an additional area in a direction perpendicular to the longitudinal direction. Accordingly, the miniaturization of the wiring board can be achieved.

The longitudinal direction typically refers to a direction parallel to a long side of a rectangular shape when the electronic elements have the rectangular shape in plan view. However, the invention is not limited to the complete rectangular shape. The shape of the electronic elements is not particularly limited, but the corners of the electronic elements are round, oval, or elongate as long as the longitudinal direction of the shape in plan view can be specified.

The mounting structure having the above-described configuration may further include a second opening which is parallel to the first opening. The electronic element is mounted between the first opening and the second opening. Moreover, the mounting structure may further include a wiring which supplies the periodic signal to the electronic element. The wiring passes between the first opening and the second opening to be connected with the electronic element. The second opening is formed to be adjacent to an opposite side opposed to one side of the electronic element. In addition, the wirings may be connected to the electrodes provided in both ends of the electronic element in the longitudinal direction and the wirings may extend in the longitudinal direction of the electronic element toward the outside of the mount area.

The second opening is provided and the electronic element is mounted between the first opening and the second opening. With such a configuration, it is possible to prevent propagation of the oscillation of the mount element mounted in any area of the wiring board, that is, an area other than the vicinity of the edge of the wiring board. By allowing the wirings between the first opening and the second wiring, it is possible to ensure the reliability of the mount portion and facilitation of a mounting process even when the electronic element is miniaturized. Moreover, since the openings provided according to the invention do not hinder connection of the wirings to the electrodes in both the ends, it is possible to mount the electronic element with high density and the wirings with high density.

When the electronic element is mounted in the vicinity of the edge of the wiring board and the electronic element is formed between the edge of the wiring board and the first opening, the second opening may not be provided.

According to the mounting structure having the above-described configuration, the first opening may have a first portion opposed to the electronic element and a second portion opposed to the wiring. The second portion is formed toward the wiring beyond an extension line of the one side of the electronic element. Moreover, each of the first opening and the second opening may have the first portion opposed to the electronic element and the second portion opposed to a wiring. The electronic elements are mounted in a first area formed between the first portions. The wiring is formed in a second area which is formed between the second portions with a width narrower than that of the first area. More specifically, both ends of the first opening in the longitudinal direction which are the second portion are curved or bent along the corners of both the ends of the electronic element in the longitudinal direction. With such a configuration, since an angle range surrounded by the opening in the periphery of the electronic element can be increased, the propagation of the oscillation to the periphery of the mount area is more reduced, thereby more reducing the sound.

Since the mount area of the electronic element in the wiring board and the width of the connection portion other than the mount area can be narrowed, it is possible to further suppress the propagation of the oscillation toward the wiring board, thereby more reducing the sound.

According to the mounting structure having the above-described configuration, a plurality of the electronic elements may be mounted between the first opening and the second opening. More specifically, the plurality of electronic elements are arranged in a direction (for example, an orthogonal direction) intersecting the longitudinal direction of the electronic elements so that the longitudinal direction of the electronic elements are parallel to each other. In addition, the plurality of electronic elements are interposed between the first opening and the second opening. With such a configuration, it is possible to mount the plurality of electronic elements with high density and effectively reduce the sound generated from the plurality of electronic elements.

When the electronic elements are mounted in the vicinity of the edge of the wiring board, the plurality of electronic elements may be mounted between the first opening and the edge of the wiring board.

In the mounting structure having the above-described configuration, inside edge corners on the electronic element side (inside) in both ends of the first or second opening in the longitudinal direction may be formed in an arc shape in plan view. By forming the inside edge corners in both the ends of the opening in the longitudinal direction in the arc shape in plan view, it is possible to reduce breakage of the wiring board or the wiring in the lower portion of the mount area of the electronic element. Specifically, when the openings are provided or the opening and a board end are provided in both the ends of the electronic element, the mount area of the electronic element is formed in a belt shape between the openings or between the opening and the board end. With such a configuration, it is possible to prevent the breakage of the lower portion of the mount area having the belt shape. In this case, it is preferable that a curvature radius of the inside edge corners is ⅓ or more of an interval between the openings or between the opening and board end. In particular, it is more preferable that the curvature radius is ½ or more of the interval. When the curvature radius varies in the inside edge corners, an average value of the curvature radius of the curved portion is equal to or larger than the above value. In particular, it is preferable that the minimum value of the curvature radius is equal to or larger than the above value.

According to another aspect of the invention, there is provided an electrooptic device including the mounting structure having the above-described configuration; and an electrooptic panel which is connected to the mounting structure.

The first opening and the second opening may not be just slits (notches), but are openings which have a sufficient width so that the edges of the openings do not contact with each other. With such a configuration, it is possible to surely prevent the oscillation from propagating beyond the slits.

According to still another aspect of the invention, there is provided an electronic apparatus comprising the electrooptic device having the above-described configuration. Examples of the electronic apparatus include a monitor device, a television receiver, and a car navigation system. In particular, the configuration according to the invention is significant in portable electronic apparatuses such as a cellular phone, a portable information terminal, an electronic clock in view of portable devices, since a reduction in the sound is highly necessary.

The wiring board is not particularly limited, but may be a rigid board formed of a glass epoxy resin or a phenol resin. In particular, the invention is very effective in a flexible printed circuit (FPC) in that the oscillation propagates with ease and the sound is easily generated.

The invention has excellent advantages of effectively reducing the sound generated due to the oscillation of the electronic element surface-mounted on the wiring board without damaging the miniaturization or thinness of the surface mounting electronic element while suppressing an increase in manufacturing cost.

### BRIEF DESCRIPTION OF THE DRAWINGS

The invention will be described with reference to the accompanying drawings, wherein like numbers reference like elements.

FIG. 1 is a schematic perspective view illustrating a configuration example of an electrooptic device according to an embodiment.

FIG. 2A is a partly enlarged perspective view illustrating a mounting structure according to a first embodiment. FIG. 2B is a vertical sectional view illustrating electronic elements.

FIG. 3 is a partly enlarged top view illustrating the mounting structure according to the first embodiment.

FIG. 4 is a partly enlarged top view illustrating a mounting structure according to a second embodiment.

FIG. 5 is a partly enlarged top view illustrating a mounting structure according to a third embodiment.

FIG. 6 is a partly top view illustrating a mounting structure according to a fourth embodiment.

FIG. 7 is a partly top view illustrating a mounting structure according to a fifth embodiment.

FIG. 8 is a diagram illustrating shape examples of openings in experiments.

FIG. 9 is a graph illustrating the experiment result.

FIG. 10 is a schematic perspective view illustrating an electronic apparatus.

FIG. 11 is a block diagram illustrating a display control system of the electronic apparatus.

### DESCRIPTION OF EXEMPLARY EMBODIMENTS

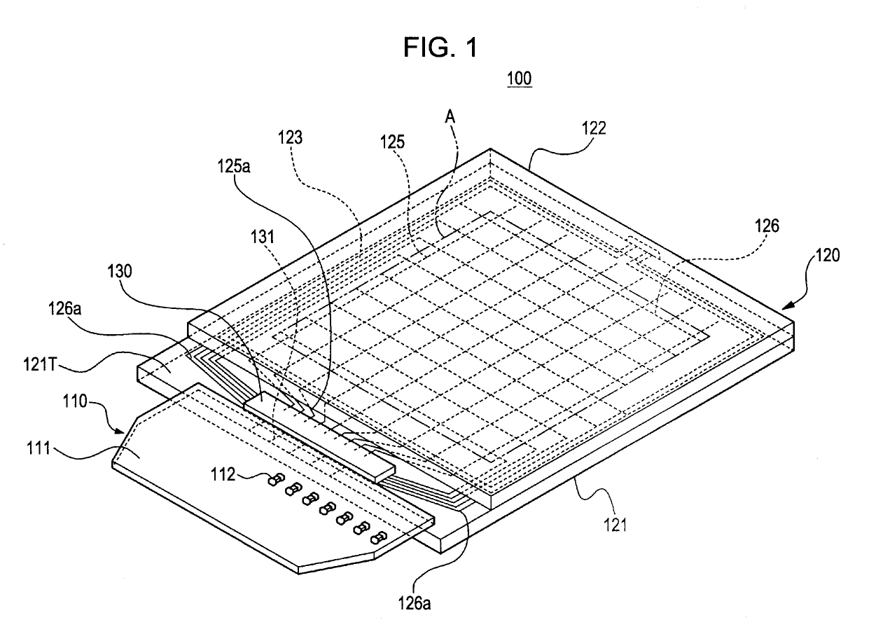

Embodiments of the invention will be described in detail with reference to the accompanying drawings. FIG. 1 is a schematic perspective view illustrating an overall configuration of an electrooptic device 100 including a mounting structure according to the embodiments of the invention. In the embodiments, the electrooptic device 100 includes a mounting structure 110. In the mounting structure 110, electronic elements 112 which are laminated ceramic capacitors, for example, are mounted on a wiring board 111 formed of a flexible printed circuit, for example. The wiring board 111 includes a plate-shaped resin member formed of an insulation resin material such as polyimide and wirings (not shown) formed of aluminum, copper, or the like on the surface of the resin member. The wiring board 111 may also include a surface resist or an overlay film for covering the resin member and the wirings, if necessary.

The electrooptic device 100 includes an electrooptic panel 120 connected to the mounting structure 110. As illustrated, the electrooptic panel 120 is formed by attaching boards 121 and 122 formed of transparent glass, plastic, or the like to each other through a seal member 123 and is configured as a liquid crystal panel by enclosing liquid crystal inside the seal member 123 having a closed shape in plan view. On both sides of the liquid crystal, a plurality of electrodes 125 and 126 formed on inner surfaces of the boards 121 and 122, respectively, are disposed so as to intersect each other in plan view and form a plurality of pixels disposed horizontally and vertically in a display area A. The plurality of electrodes 125 and 126 are connected to wirings 125a and 126a, respectively. The plurality of wirings 125a and 126a are provided an end of the board 121 and drawn onto a board extension portion 121T formed by extending outside more than the appearance of the board 122.

An integrated circuit 130 (IC chip) conductively connected to the wirings 125a and 126a is mounted on the surface of the board extension portion 121T. The integrated circuit 130 includes a driving circuit applying a predetermined driving signal to the electrodes 125 and 126 of the electrooptic panel 120. In addition, there are also formed a plurality of input wirings 131 which are connected to the integrated circuit 130 and extend toward the end edge of the board extension portion 121T. The input wirings 131 are conductively connected to wirings (not shown) of the wiring board 111 which are mounted in the end edge of the board extension portion 121T.

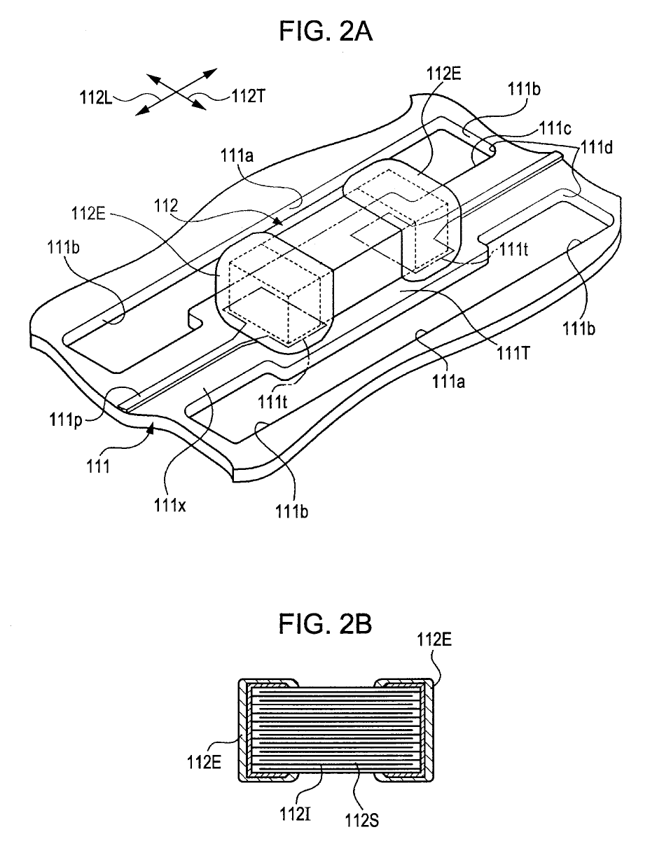

FIG. 2A is a partly enlarged perspective view illustrating a mount range according to a first embodiment of the invention. FIG. 2B is a vertical sectional view illustrating the inner structure of the electronic elements. In this embodiment, as shown in FIG. 2A, the electronic elements 112 are mounted on the surface of the wiring board 111 and have a substantially rectangular shape in plan view. Specifically, the electronic elements 112 have the rectangular shape in plan view and have a substantially rectangular parallelepiped shape on the whole. External electrodes 112E are formed in both ends in a longitudinal direction 112L (a direction of a long side of the rectangular shape) of the electronic elements 112. The external electrodes 112E have a structure for covering the surface of a metal layer formed of aluminum with a solder layer, for example.

As shown in FIG. 2B, inner electrodes 112I formed of aluminum or the like and dielectric layers 112S formed of a ceramic sheet are alternatively laminated in a thickness direction inside the electronic elements 112. When viewed in the thickness direction, a plurality of the inner electrodes 121I are conductively connected to one and the other of a pair of the external electrodes 112E formed in both the ends.

A pair of mount electrodes 111t corresponding to the external electrodes 112E are formed in a mount area 111T of the wiring board 111. Board wirings 111p extending on a side opposite the other of the mount electrodes 111t in the longitudinal direction 112L are connected to the mount electrodes 111t so as to be integrated. The external electrodes 112E of the electronic elements 112 are conductively connected to the mount electrodes 111t through soldering or the like. Mounting the electronic elements 112 on the wiring board 111 is performed by a known soldering reflow process (a coating process, a reflow heating process, and the like of a cream solder layer), for example.

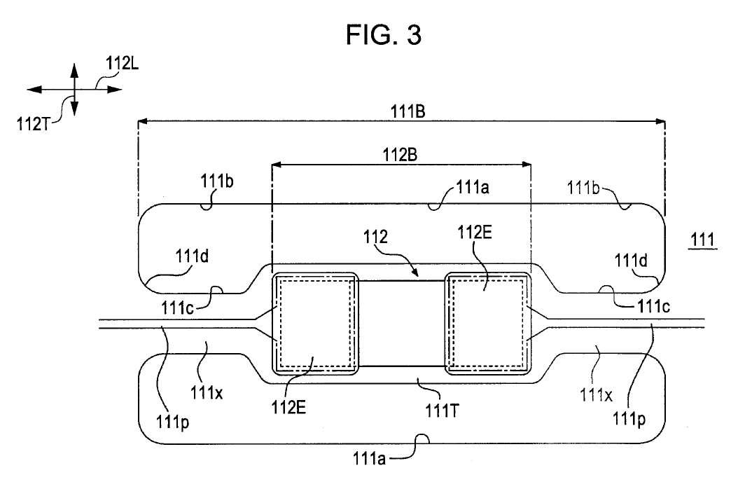

FIG. 3 is a partly enlarged top view illustrating the mount range according to this embodiment. As shown in FIG. 3, a pair of openings 111a are formed in an adjacent manner on both sides of the mount area 111T of the wiring board 111. Each of the openings 111a has s shape extending in a horizontal direction of the drawing along the outside edge of the mount area 111T in the longitudinal direction 112L. In addition, a range 111B of the openings 111a in the longitudinal direction 112L contains a range 112B of the electronic element 112 at least in the longitudinal direction 112L. That is, on the assumption that a direction perpendicular to the longitudinal direction 112L is an orthogonal direction 112T in a virtual plane extending along the surface of the wiring board 111, a virtual line (illustrated by a one dotted line) extending in the orthogonal direction 112T from both end edges of the electronic element 112 in the longitudinal direction 112L intersects the openings 111a in plan view.

With such a configuration of the openings 111a, oscillation propagated from the longer side of the electronic element 112 to the outside (in the orthogonal direction 112T) is blocked by the openings 111a. In particular, the oscillation generated from the electronic element 112 is blocked on both the sides of the board, since the openings 111a are formed on both the sides of the electronic element 112 in the orthogonal direction 112T. As illustrated, each of the openings 111a covers the range 112B of the electronic element 112 in the longitudinal direction 112L and also includes opening extension portions 111b extending on both sides in the longitudinal direction 112L more than the range 112B. Accordingly, an angle range of the opening 111a surrounding the mount area 111T of the electronic element 112 increases, thereby reducing the propagation of the oscillation toward the periphery.

Each of the openings 111a includes opening bulge portions 111c extending toward the inside (the electronic element 112 and the board wirings 111p) in both ends (that is, the opening extension portions 111b) thereof in the longitudinal direction 112L to surround the corners of the mount area 111T. The opening portion 111a is curved or bent inward in both the ends thereof on the whole so that the opening bulge portions 111c are formed to be wound from the outside edges of the mount area 111T to both the ends in the longitudinal direction 112L or to be wound from the longer sides to the shorter sides of the electronic element 112. With such a configuration, the angle range of the openings 111a surrounding the mount area 111T further increases.

Since the openings 111a are formed on both the sides of the electronic element 112 in the orthogonal direction 112T, the mount area 111T is formed in a belt shape on the whole and connected to both sides of the wiring board 111 in the longitudinal direction 112L through connection portions 111x. At this time, it is preferable that the connection portions 111x are formed so as to have a width narrower than that of the mount area 111T. In this embodiment, the connection portions 111x have the width narrower than that of the mount area 111T by a bulging size of the opening bulge portions 111c by forming the opening bulge portions 111c in each of the openings 111a. The mount area 111T and the connection portions 111x on both the sides of the mount area 111T form the belt shape of the periphery of the wiring board 111.

In this case, as described above, the opening portions 111a cover the entire range 112B of the electronic element 112 in the longitudinal direction 112L. Accordingly, the belt-shaped portion (the mount area 111T and the connection portions 111x on both the sides thereof in the longitudinal direction) is formed so as to be narrow and long. Accordingly, since the belt-shaped portion has high flexibility and the connection portions 111x has the narrow width, it is difficult for oscillation of the electronic element 112 to propagate to the periphery of the wiring board.

In this embodiment, it is preferable that the openings 111a have no simple slit (notch) but have some width so that the opening edges on both opposite sides do not contact with each other, as illustrated. With such a configuration, it is possible to surely prevent the oscillation from propagating beyond the slit.

The board wirings 111p extends outside through the inside of the connection portions 111x. That is, the board wirings hip extend from the mount electrodes 111t in the longitudinal direction 112L so as to have a straight line shape. With such a configuration, it is possible to ensure the formation range of the openings 111a when the board wirings 111p extend from the mount electrodes 111t.

Corners 111d formed in the inside edges of both the ends of the opening 111a in the longitudinal direction 112L are formed in an arc shape in plan view. By forming the inside edge corners 111d in the arc shape, it is possible to improve an yield in manufacture of the wiring board 111 or the mounting structure 110 since the resin member or the board wirings 111p is rarely broken even in the narrow width of the belt-shaped portion. Moreover, in the manufacture of the wiring board 111, the openings 111a can be formed with ease. It is preferable that the openings 111a are subjected to a punching process simultaneously with the appearance of the wiring board 111. However, by forming the inside edge corners 111d in the arc shape in the punching process, the punching process can be performed with more ease and durability of a cutting blade can be improved.

It is preferable that a curvature radius of the inside edge corners 111d is at least larger than a line width of the board wirings 111p. In particular, it is preferable that the curvature radius of the inside edge corners 111d is larger than ⅓ of the width of connection portions 111x. With such a configuration, it is possible to considerably reduce the breakage of the resin member or the board wirings 111p in a base portion of the belt-shaped portion. In addition, it is preferable that the curvature radius of the inside edge corners 111d is larger than ½ of the width of the connection portions 111x. With such a configuration, it is possible to prevent the breakage of the resin member or the board wirings 111p in the base portion of the belt-shaped portion even when the opening bulge portions 111c are provided and the connection portions 111x are provided to have the narrow width like the above-description.

When the inside edge corners 111d are formed in an inside edge shape in which the curvature radius varies, an average value of the curvature radius of the curved portion is set to be equal to or larger than the above-mentioned value. In particular, it is preferable that the minimum value of the curvature radius is equal to or larger than the above-mentioned value. In addition, the opening 111a is not limited to the inside edge corners 111d, but the inside edge corners 111d may be formed so that the inside edges of all the corners have a curvature radius larger than the above-mentioned curvature radius. With such a configuration, it is possible to ensure the yield or manufacture facilitation of the wiring board 111.

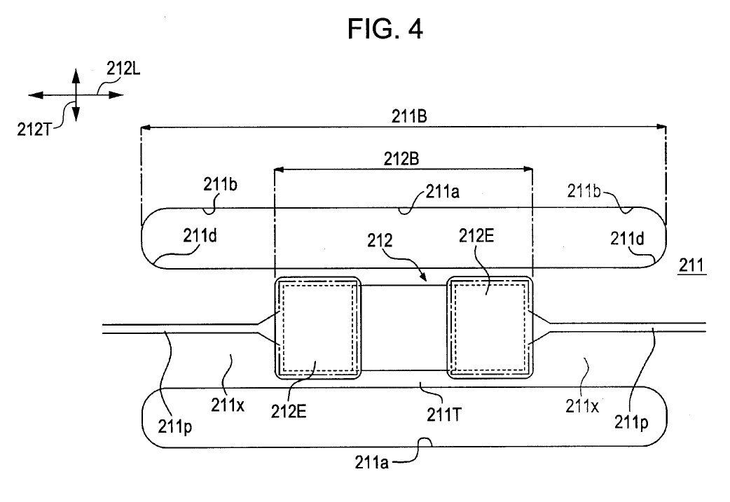

FIG. 4 is a partly enlarged top view illustrating a configuration according to a second embodiment of the invention. This embodiment has the same configuration as that of the first embodiment in that openings 212a are formed on both sides of a mount area 211T of the wiring board 211 mounted with each electronic element 212 in an orthogonal direction 212T; the openings 211a are formed so as to extend in a longitudinal direction 212L, covers an entire range 212B of each electronic element 212 in the longitudinal direction 212L, arid each include opening extension portions 211b extending from the range 212B in the longitudinal direction 212L; and inside edge corners 211d are formed in an arc shape in plan view. However, this embodiment has a different configuration from that of the first embodiment in that the entire opening 211a extends in a straight line shape in the longitudinal direction 212L and the opening bulge portions 111c according to the first embodiment are not formed.

The wiring board described in this specification is a rigid board formed of a resin material such as a glass epoxy resin or a phenol resin, but it is preferable that the wiring board is the flexible printed circuit (FPC) described above. The flexible printed circuit facilitates propagation of oscillation generated from the electronic element 112 and also facilitates the generation of a sound.

In this embodiment, the openings 211a are likewise formed so as to be adjacent to both outsides of the longer sides of the electronic element 212 and to cover the entire range 212B of the electronic element 212 in the longitudinal direction 212L and the opening extension portions 211b are formed in both ends of each of the openings 211a. Accordingly, it is possible to effectively block the oscillation of the electronic element 212 while reducing an influence of the wiring board 211 on wirings as small as possible.

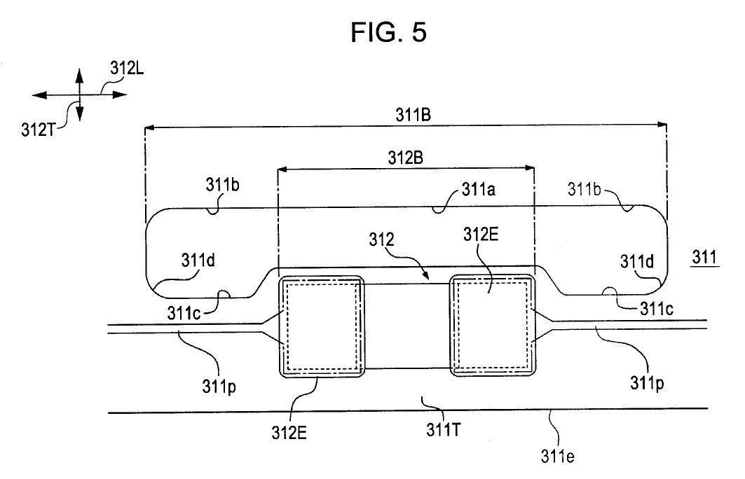

FIG. 5 is a partly enlarged top view illustrating a configuration according to a third embodiment of the invention. In this embodiment, each electronic element 312 is mounted so as to be adjacent to a board end 311e of a wiring board 311 along the board end 311e in a longitudinal direction 312L. In addition, an opening 311a is formed opposite the board end 311e in an orthogonal direction 312T. The opening 311a has the same shape (opening extension portion 311b, opening bulge portions 311c, and inside edge corners 311d) as that according to the first embodiment, except that the opening 311a is formed only on one side of the electronic element 312.

In this embodiment, the electronic elements 312 is mounted between the opening 311a and the board end 311e. Accordingly, it is possible to obtain the almost same advantages of the configuration in which the openings are formed on both the sides according to the first and second embodiments described above. Moreover, with such a configuration, it is sufficient that the opening 311a is just formed on the one side of the electronic element 312. Accordingly, it is possible to reduce an area occupied by the wiring board 311.

In this case, the opening 311a including the arc-shaped inside edge corners 311d (or including no corners) has the same shape as that according to the second embodiment. However, by providing the opening bulge portions 311c as illustrated, it is possible to obtain better advantages.

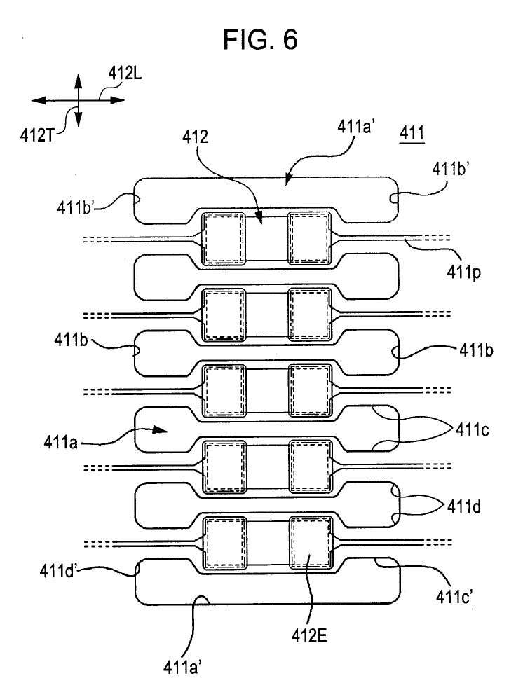

FIG. 6 is a partly enlarged top view illustrating a configuration example in which a plurality of electronic elements 412 are mounted on a wiring board 411 in a mounting structure according to the invention. As illustrated, the plurality of electronic elements 412 mounted on the wiring board 411 are arranged in an orthogonal direction 412T so as to be parallel to each other in the longitudinal direction 412L. In this case, openings 411a are interposed between the electronic elements 412 and openings 411a′ are disposed so as to be adjacent to the outside ends of the plurality of electronic elements 412. In addition, the arrangement direction of the plurality of electronic elements is not limited to the orthogonal direction 412T, but may be a direction intersecting the longitudinal direction 412L.

Each of the openings 411a interposed between the electronic elements 412 has a symmetric opening shape with respect to the pair of electronic elements 412 adjacent to each other. That is, as illustrated, each of the openings 411a includes opening extension portions 411b in both ends thereof in the longitudinal direction 412L and also includes opening bulge portions 411c bulging form the opening extension portions 411b toward both sides in the orthogonal direction 412T. Inside edge corners 411d formed in the opening extension portions 411b are also provided in the same manner according to the first embodiment.

Each of the openings 411a′ formed on both the ends of the arrangement of the electronic elements 412 includes opening extension portions 411b′ on both ends thereof in the longitudinal direction 412L in the same manner according to the first embodiment. However, only opening bulge portions 411c′ bulging inward in the orthogonal direction 412T from the opening extension portions 411b′ is formed. Inside edge corners 411d′ formed in the opening extension portions 411b′ are formed in the same manner according to the first embodiment.

When the plurality of electronic elements are arranged in the orthogonal direction in the above-described manner, the oscillation propagating in the orthogonal direction from the electronic elements can be blocked by providing the openings between the electronic elements. Moreover, by improving the flexibility of areas where the electronic elements are mounted, it is possible to suppress the propagation of the oscillation toward the periphery.

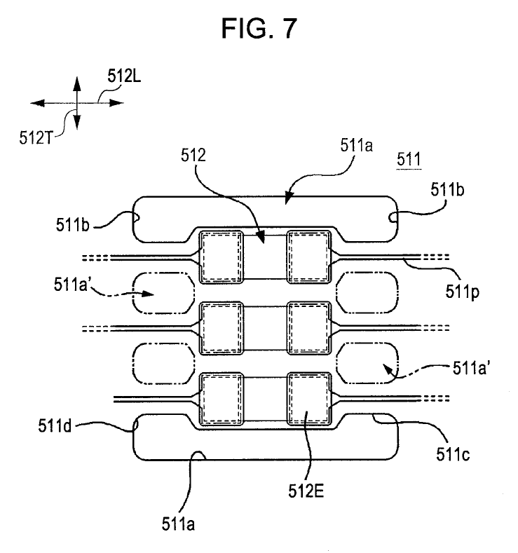

FIG. 7 is a partly enlarged top view illustrating a modified example of the mounting structure described above. In the modified example, a plurality of electronic elements 512 are arranged on a wiring board 511 in the above-described manner and in the above-described direction. In this case, openings 511a of the wiring board 511 are not formed between the electronic elements 512 but are formed only on the outside ends of arrangement of the plurality of electronic elements 512. Each of the openings 511a includes opening extension portions 511b, opening bulge portions 511c, and inside edge corners 511d described above. In this case, the opening bulge portions 511c are formed only on the side of the electronic elements 512. In addition, an arrangement direction of the plurality of electronic elements is not limited to an orthogonal direction 512T but may be a direction intersecting a longitudinal direction 512L.

This modified example is suitable for the plurality of electronic elements 512 mounted with high density. When the electronic elements 512 are mounted with the high density, there is no sufficient space where openings are formed between the electronic elements 512. Even when the openings are formed between the electronic elements 512, the openings cannot be formed with high precision or durability of a punching blade cannot be obtained. However, in order to suppress the propagation of the oscillation, side openings 511a′ illustrated by two dotted lines may be formed in areas deviated from the areas between the electronic elements 512 in the longitudinal direction 512L. As illustrated, the side openings 511a′ are formed between board wirings 511p connected to mount terminals.

When the plurality of electronic elements are arranged in this manner, it is possible to block all oscillation generated from the plurality of electronic elements from propagating toward the periphery by providing the openings in the area where the plurality of electronic elements are arranged.

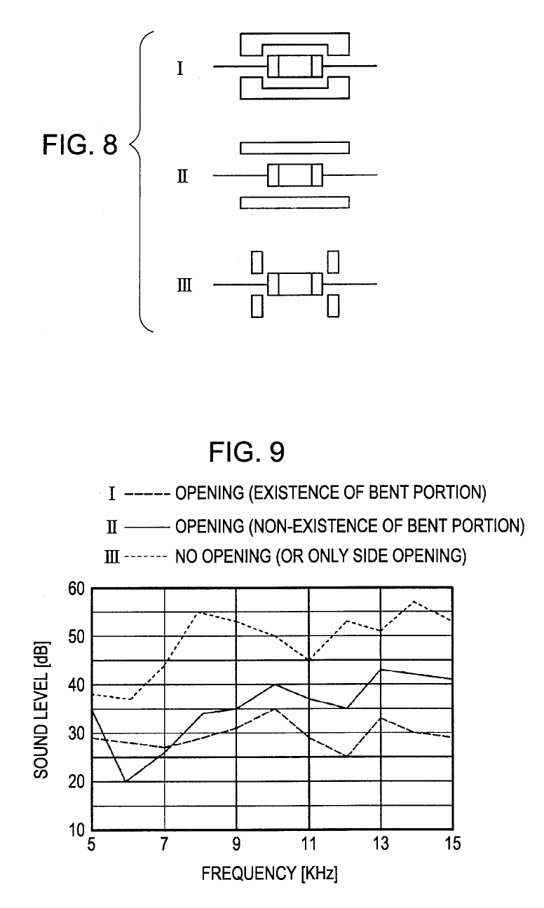

FIG. 8 is a top view illustrating shape examples of openings when an equal electronic element (a laminated ceramic capacitor) mounted on an equal wiring board (flexible printed circuit) and a sound generated from the wiring board due to the oscillation of the electronic element is measured by varying the shape of the openings mounted on the wiring board. FIG. 9 is a graph illustrating the measurement result of the sound.

Case I of FIG. 8 shows that the openings are formed on both the sides of the electronic element in the orthogonal direction so as to extend the longitudinal direction, to extend more than the range of the electronic elements from both the ends of the electronic element in the longitudinal direction, and to be bent inward in the same manner as that in the first embodiment. Case II of FIG. 8 shows that the openings are formed in the straight line shape on the while so as to extend in the longitudinal direction and to extend more than the range of the electronic element from both the ends of the electronic element in the longitudinal direction in the same manner as that in the second embodiment. Case III of FIG. 8 shows that each wiring is connected to both sides of the electronic elements in the longitudinal direction and two side openings are each formed.

As shown in FIGS. 8 and 9, a sound level is reduce by the range from 20 dB to 25 dB on the average in the case (Case I in the drawing) where the openings having the same shape as that in the first embodiment are formed, compared to a case where the opening is not formed or the case (Case III in the drawing) where the plurality of side openings are formed on both the sides of the electronic element in the longitudinal direction. In addition, the sound level is reduced by the range from 10 dB to 15 dB in the case (Case II in the drawing) where the openings having the same straight line shape as that in the second embodiment are formed. However, in the case where only the side openings of Case III in the drawing are formed, a meaningful result cannot be obtained like the case where the opening is not formed. As a result, it can be concluded that the configuration in which the openings are formed on both the sides of the electronic element in the orthogonal direction to extend in the longitudinal direction is effective.

Now, an electronic apparatus mounted with the electrooptic device 100 according to the above-described embodiments will be described. FIG. 10 is a diagram illustrating a cellular phone as an example of the electronic apparatus according to the invention. As illustrated, a cellular phone 200 includes a plurality of manipulation buttons, a manipulation unit 201 including a mouth piece, and a display unit 202 including an ear piece. The electrooptic device 100 is mounted within the display unit 202. The display area A of the electrooptic device 100 can be viewed on the surface (inner surface) of the display unit 202. In this case, a display control circuit or the like controlling the electrooptic device 100 is provided inside the cellular phone 200. The display control circuit transmits a predetermined control signal to a known drive circuit driving the electrooptic panel 120 to determine a display aspect of the electrooptic device 100.

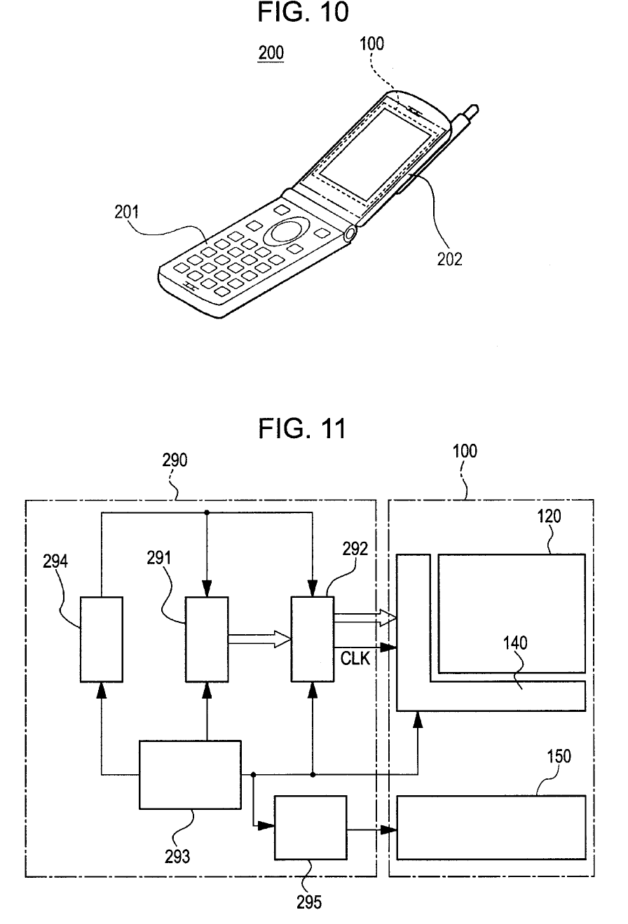

FIG. 11 is a schematic block diagram illustrating an entire configuration of a control system (display control system) of the electrooptic apparatus 100 in the electronic apparatus. The illustrated electronic apparatus (the cellular phone 200) includes the display control circuit 290 which includes a display information output source 291, a display information processing circuit 292, a power circuit 293, a timing generator 291, and a light source control circuit 295 supplying power to a backlight 150. The electrooptic device 100 includes the electrooptic panel 120 as a liquid crystal display member having the above-described configuration, a drive circuit 140 driving the electrooptic panel 120, and the backlight 150. The drive circuit 140 includes the above-described mounting structure 110 directly mounted in the electrooptic panel 120 and an integrated circuit 130. At this time, in addition to the above-described configuration, the drive circuit 140 may be configured by electronic elements or a circuit pattern formed on the board surface of the electrooptic panel 120 or by a semiconductor IC chip or a circuit pattern mounted in the circuit board conductively connected to the electrooptic panel 120.

The display information output source 291 includes a memory formed of a ROM (Read-Only Memory), a RAM (Random Access Memory), or the like, a storage unit formed of a magnetic record disk, an optical record disk, or the like, and a tuning circuit synchronizing and outputting a digital image signal. On the basis of various clock signals generated by the timing generator 294, the display information output source 291 supplies display information to the display information processing circuit 292 in the form of an image signal having a predetermined format.

The display information processing circuit 292 includes known circuits such as a serial-parallel conversion circuit, an amplification/inversion circuit, a rotation circuit, a gamma correction circuit, and a clamp circuit. The display information processing circuit 292 processes input display information to supply the image information and a clock signal CLK to the drive circuit 140. The drive circuit 140 includes a scanning line drive circuit, a signal line drive circuit, and an inspection circuit. The power circuit 293 supplies respective predetermined voltage to the constituent elements described above.

The light source control circuit 295 supplies power to a light source of the backlight 150 on the basis of the voltage supplied from the power circuit 293 and controls lighting and the brightness of the light source on the basis of a predetermined control signal.

Examples of the electronic apparatus according to the invention include a liquid crystal television, a car navigation device, an electronic pocket book, a calculator, a workstation, a television telephone, and a POS terminal in addition to the cellular phone illustrated in FIG. 10. In addition, as a display unit of the various electronic apparatuses, the liquid crystal display device according to the invention may be used. At this time, since the liquid crystal display device according to the invention is capable of reducing the sound, the liquid crystal display device is particularly effective in portable electronic apparatuses such as a cellular phone, an electronic clock, and a portable information terminal.

The invention is not limited to the illustrated examples described above, but may be modified in various forms within the range without departing the gist of the invention. For example, in these embodiments, the liquid crystal display device including the liquid crystal display panel is described. However, the invention is not limited to the liquid crystal display device, but may applied to other electrooptic devices including an electrooptic panel, such as an organic luminescence display device, a field emission display device, a plasma display device, an electronic portal imaging device.

The entire disclosure of Japanese Patent Application Nos. 2007-322919 filed Dec. 14, 2007 and 2008-183506 filed Jun. 15, 2008 are expressly incorporated by reference herein.

What is claimed is:

1. A mounting structure comprising:
a wiring board;
an electronic element which is mounted in the wiring board and supplied with a periodic signal; and
a first opening which is formed in the wiring board along one side of the electronic element in a longitudinal direction of the electronic element,
wherein the opening is opposed to the entire one side of the electronic element.

2. The mounting structure according to claim 1, wherein the electronic element is formed so that voltage is applied in a direction intersecting a plane direction of the wiring board.

3. The mounting structure according to claim 2, wherein the electronic element is formed by inserting an electrostrictive material between a pair of electrodes.

4. The mounting structure according to claim 1,
wherein the first opening includes a first portion opposed to the electronic element and a second portion opposed to a wiring, and
wherein the second portion is formed toward the wiring beyond an extension line of the one side of the electronic element.

5. The mounting structure according to claim 1, further comprising:
a second opening which is parallel to the first opening,
wherein the electronic element is mounted between the first opening and the second opening.

6. The mounting structure according to claim 5, further comprising:
a wiring which supplies the periodic signal to the electronic element,
wherein the wiring passes between the first opening and the second opening to be connected with the electronic element.

7. The mounting structure according to claim 5, wherein a plurality of the electronic elements are mounted between the first opening and the second opening.

8. The mounting structure according to claim 5,
wherein each of the first opening and the second opening has a first portion opposed to the electronic element and a second portion opposed to a wiring,
wherein the electronic elements are mounted in a first area formed between the first portions, and
wherein the wiring is formed in a second area which is formed between the second portions with a width narrower than that of the first area.

9. An electrooptic device comprising:
the mounting structure according to claim 1; and
an electrooptic panel which is connected to the mounting structure.

10. An electronic apparatus comprising the electrooptic device according to claim 9.
